(19) United States
(12) Patent Application Publication
(10) Pub. No.: US 2025/0174279 A1
(43) Pub. Date: May 29, 2025

(54) PAGE BUFFERS AND OPERATION METHODS THEREOF, AND MEMORY DEVICES AND MEMORY SYSTEMS

(71) Applicant: Yangtze Memory Technologies Co., Ltd., Wuhan (CN)

(72) Inventor: Weiwei He, Wuhan (CN)

(21) Appl. No.: 18/614,163

(22) Filed: Mar. 22, 2024

(30) Foreign Application Priority Data
Nov. 27, 2023 (CN) 202311608082.3

(51) Int. Cl. G11C 16/24; G11C 16/04; G11C 16/30

(52) U.S. Cl. CPC G11C 16/24; G11C 16/0483; G11C 16/30

(57) ABSTRACT

Examples of the present application relate to the field of semiconductors, and disclose a page buffer and an operation method thereof, a memory device and a memory system. The page buffer includes latch circuits, wherein the latch circuits includes: a latch control configuration circuit connected with a first data node and a second data node, and configure the first data node and the second data node to different logic levels respectively in response to a configuration signal, wherein a logic level of the first data node is opposite to a logic level of the second data node; and a latch transmission circuit connected with the first data node, the second data node, and a sense node, and configured to: couple the second data node with the sense node in response to a transmission signal, to transmit a configuration result of the latch control configuration circuit to the sense node.

### CROSS REFERENCE TO RELATED APPLICATION

This application claims priority to and the benefit of Chinese Patent Application 202311608082.3, filed on Nov. 27, 2023, which is hereby incorporated by reference in its entirety.

### TECHNICAL FIELD

Examples of the present application relate to semiconductor technology, and relate to, but are not limited to, page buffers and operation methods thereof, memory devices and memory systems.

### BACKGROUND

Semiconductor memories may be roughly divided into two types, depending on whether the stored data can be retained during power failure. The two types of semiconductor memories comprise a volatile memory and a non-volatile memory, wherein the volatile memory loses the stored data during power failure, and the non-volatile memory retains the stored data during power failure. Memory cells in the non-volatile memory are connected to bit lines and word lines respectively, and thus have good random access time characteristics.

### BRIEF DESCRIPTION OF THE DRAWINGS

In the drawings, like reference numerals may describe like parts in the different views. Like reference numbers with different letter suffixes may indicate different examples of like parts. The drawings illustrate the various examples discussed herein, by way of example and not limitation.

FIG. 1 is a schematic structural diagram of an electronic system provided by an example of the present application;

FIG. 2 is a schematic structural diagram of a memory card provided by an example of the present application;

FIG. 3 is a schematic structural diagram of a Solid State Disk (SSD) provided by an example of the present application;

FIGS. 4 and 5 are schematic structural diagrams of a memory comprising a memory cell array and a peripheral circuit provided by an example of the present application;

FIG. 6 is a schematic structural diagram of a memory comprising a page buffer group provided by an example of the present application;

FIG. 7 is a schematic diagram of a page buffer provided by an example;

FIG. 8 is a schematic diagram I of a page buffer provided by examples of the present application;

FIG. 9 is a schematic diagram II of a page buffer provided by examples of the present application;

FIG. 10 is a schematic diagram I of a latch circuit of a page buffer provided by examples of the present application;

FIG. 11 is a schematic diagram II of a latch circuit of a page buffer provided by examples of the present application;

FIG. 12 is a schematic diagram I of a partial logic circuit of a latch circuit of a page buffer provided by examples of the present application;

FIG. 13 is a schematic diagram II of a partial logic circuit of a latch circuit of a page buffer provided by examples of the present application;

FIG. 14 is a schematic diagram III of a partial logic circuit of a latch circuit of a page buffer provided by examples of the present application;

FIG. 15 is a schematic diagram IV of a partial logic circuit of a latch circuit of a page buffer provided by examples of the present application;

FIG. 16 is a schematic diagram of a logic circuit of a latch circuit of a page buffer provided by examples of the present application;

FIG. 17 is a schematic structural diagram I of a voltage regulator circuit of a page buffer provided by examples of the present application;

FIG. 18 is a schematic diagram I of a logic circuit of a voltage regulator circuit of a page buffer provided by examples of the present application;

FIG. 19 is a schematic diagram II of a logic circuit of a voltage regulator circuit of a page buffer provided by examples of the present application;

FIG. 20 is a schematic diagram of logic circuits of a bit line control circuit and a bit line discharging circuit of a page buffer provided by examples of the present application;

FIG. 21 is a schematic diagram of a logic circuit of a page buffer provided by examples of the present application;

FIG. 22A is a timing diagram I of a latch circuit of a page buffer provided by examples of the present application;

FIG. 22B is a timing diagram II of a latch circuit of a page buffer provided by examples of the present application;

FIG. 23 is a flowchart of an operation method of a page buffer provided in FIG. 22A; and

FIG. 24 is a flowchart of an operation method of a page buffer provided in FIG. 22B.

### DETAILED DESCRIPTION

In order to facilitate the understanding of the present application, the present application will be described below more comprehensively with reference to the drawings. Examples of the present application are given in the drawings. However, the present application may be implemented in many different forms, and is not limited to the examples described herein. Instead, the purpose of providing these examples is to make the disclosure of the present application more thorough and comprehensive.

Unless otherwise defined, all technical and scientific terms used herein have the same meanings as those understood by those skilled in the art. The terms used in the specification of the present application are only for the purpose of describing examples, and are not intended to limit the present application. The term “at least one of . . . ” used herein include any and all combinations of one or more listed associated items.

As used in the present application, “first,” “second,” and similar phases do not denote any order, quantity, or importance, but are merely used to distinguish different components. Similarly, similar terms such as “a”, “one” or “the” do not indicate a quantitative limitation, but rather the existence of at least one. Similar phases such as “comprising” or “including” are intended to mean that the element or object appearing before the phase covers the element or object appearing after the phase listed and equivalent thereof, without excluding other elements or objects. Similar terms such as “connection” or “connected” or “coupled” are not limited to physical or mechanical connection, but may include electrical connection, whether direct or indirect.

In order to understand the present application thoroughly, detailed operations and detailed structures will be proposed in the following description to set forth the technical solution of the present application. The detailed descriptions of the examples of the present application are as follows. However, the present application may also have other examples in addition to these detailed descriptions.

As the integration level of the memorys increases, the area occupied by a page buffer in the peripheral circuit of a memory device is limited, and there is a need for the reduction of the area of the page buffer, such that the number of elements constituting the page buffer also needs to be simplified.

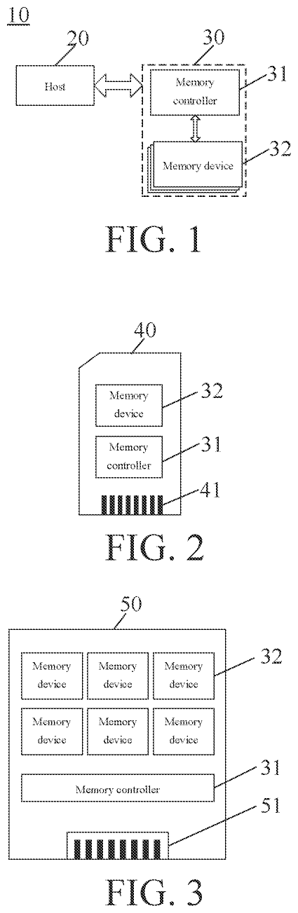

As shown in FIG. 1, the examples of the present application show an electronic system 10. In an example, the electronic system 10 may include, but is not limited to, a mobile phone, a desktop computer, a laptop computer, a tablet computer, a vehicle computer, a gaming console, a printer, a positioning device, a wearable electronic device, a smart sensor, a Virtual Reality (VR) device, an Augmented Reality (AR) device, or a system of any other suitable electronic device having a memory device 32.

Continuously referring to FIG. 1, the electronic system 10 may comprise a host 20 and a memory system 30.

The host 20 may be a processor of an electronic device (such as a Central Processing Unit (CPU), or a System on Chip (SoC) (such as an Application Processor (AP)). The host 20 may be configured to send or receive data to or from the memory system 30.

The memory system 30 comprises a memory controller 31 and one or more memory devices 32, and other integrated circuit structures for signal transmission. The memory controller 31 and the one or more memory devices 32 may be integrated and packaged in the same storage device. In this way, the memory system 30 is applied to different types of end electronic products.

In an example, a type of the storage device integrating the memory controller 31 and the one or more memory devices 32 comprises: a Universal Flash Storage (UFS) or Embedded Multi Media Card (eMMC) and other type of storage devices.

There are various ways in which the integrated circuit of the storage device can be formed, such as a memory card 40 (shown in FIG. 2) formed by integrating a single memory device 32 and a memory controller 31 together, or an SSD 50 (shown in FIG. 3) formed by integrating a plurality of memory devices 32 and a memory controller 31 together.

In an example, the memory card 40 may comprise one or more types of storage devices such as a Personal Computer Memory Card International Association (PC) card, a CF card, a Smart Media (SM) card, a memory stick, a Multi-Media Card (MMC, Reduced-Size MMC (RS-MMC), MMC micro), an SD card (SD, miniSD, microSD, Secure Digital High Capacity (SDHC)), and UFS.

Continuously referring to FIG. 2, the memory card 40 further comprises a memory card connector 41. The memory card connector 41 is configured to couple the memory card 40 with a host (for example, the host 20 in FIG. 1). For example, the memory card connector 41 comprises a golden finger.

Alternatively, continuously referring to FIG. 3, the SSD 50 further comprises an SSD connector 51. The SSD connector 51 is configured to couple the SSD 50 with the host (for example, the host 20 in FIG. 1). For example, the SSD connector 51 comprises the golden finger.

It can be understood that at least one of the storage capacity or operation speed of the SSD 50 is greater than that of the memory card 40.

The above-mentioned memory controller 31 is coupled with the memory device 32 (and the host 20) integrated in the same storage device, and the memory controller 31 is configured to control the memory device 32.

In an example, the memory controller 31 may be designed for operating in a low duty cycle environment, for example, for operating in Secure Digital (SD) cards, Compact Flash (CF) cards, Universal Serial Bus (USB) flash drives, or other media for use in electronic devices, such as personal computers, digital cameras, mobile phones, etc. In another example, the memory controller 31 may be designed for operating in a high duty cycle environment, for example, for operating in SSDs or embedded Multi-Media Cards (eMMC). The SSD and the eMMC may serve as a data storage for a mobile device, such as a smart phone, a tablet computer, and a laptop computer, etc., and an enterprise memory array.

Furthermore, the memory controller 31 may manage data stored in the memory device 32 and communicate with the host 20. The memory controller 31 may be configured to control read, erase and program operations of the memory device 32, and may be further configured to manage various functions with respect to data stored or to be stored in the memory device 32, including, but not limited to, bad-block management, garbage collection, logical-to-physical address conversion, wear leveling, etc. The memory controller 31 may further be configured to process Error Checking and Correction (ECC) with respect to the data read from or written to the memory device 32.

Furthermore, the memory controller 31 may further perform any other suitable functions as well, for example, formatting the memory device 32 or communicating with an external device (for example, the host 20 in FIG. 1) according to a particular communication protocol. For example, the memory controller 31 may communicate with the host 20 according to at least one of various interface protocols. The interface protocols comprise one or more of a USB protocol, an MMC protocol, a Peripheral Component Interconnect (PCI) protocol, a Peripheral Component Interconnect Express (PCI-E) protocol, an Advanced Technology Attachment (ATA) protocol, a serial ATA protocol, a parallel ATA protocol, a Small Computer System Interface (SCSI) protocol, an Enhanced Small Drive Interface (ESDI) protocol, an Integrated Development Equipment (IDE) protocol, and a Firewire protocol, etc.

The memory device 32 may include, but is not limited to, a NAND Flash Memory, a Vertical NAND Flash Memory, a NOR Flash Memory, a Dynamic Random Access Memory (DRAM), a Ferroelectric Random Access Memory (FRAM), a Magnetoresistive Random Access Memory (MRAM), a Phase Change Random Access Memory (PCRAM), a Resistive Random Access Memory (RRAM), a Nano Random Access Memory (NRAM), etc.

Based on the above-mentioned descriptions, in the present application, taking the memory device 32 as a semiconductor memory, for example, a solid state electronic device (for example, a NAND-type memory) manufactured by a semiconductor integrated circuit process for storing data information as an example to describe the following examples. An internal structure of the memory device 32 is not limited in the following examples of the present application.

It can be understood that for ease of distinguishing cases in which the memory device 32 is adapted for application to different scenarios, for example, various structures of the memory device 32 based on the examples in the aforementioned content, taking the memory device 60 as the memory device (for example, the NAND-type memory) provided by the following examples of the present application.

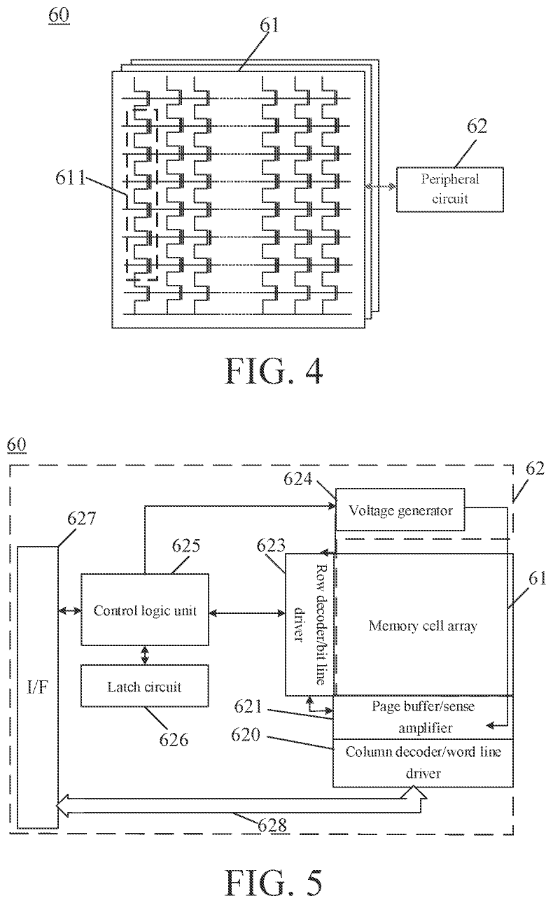

As shown in FIG. 4, in some examples, the memory device 60 may comprise a memory cell array 61 and a circuit structure, such as a peripheral circuit 62, coupled to the memory cell array 61.

The memory cell array 61 is connected with a plurality of bit lines. In an example, the memory cell array 61 may be a NAND flash memory cell array. For example, the memory cell array 61 is a circuit structure disposed in the form of an array arrangement of NAND memory strings 611. Each NAND memory string 611 extends vertically on a substrate. In an example, each NAND memory string 611 may comprise a plurality of memory cells coupled in series and stacked vertically. Each memory cell is in a state that holds a continuous analog value (for example, voltage or charge) for signal transmission, and the analog value of the memory cell depends on the number of electrons trapped within a region of the memory cells.

In an example, each memory cell in the memory cell array 61 can be either a floating gate type of memory cell including a floating-gate transistor or a charge trap type of memory cell including a charge-trap transistor. The present application is not limited thereto.

In some example, a storage type of the above-mentioned memory cell comprises any one of a Single Level Cell (SLC), a Multi Level Cell (MLC), a Triple Level Cell (TLC), and a Quad Level Cell (QLC), etc.

In an example, each memory cell of the SLC may store one bit of data, and has two possible memory states, i.e., a first memory state and a second memory state. The first memory state (for example, “0”) corresponds to a first threshold voltage range, and the second memory state (for example, “1”) corresponds to a second threshold voltage range. In this way, the second memory state (for example, “1”) is used for an erased state, and the first memory state (for example, “0”) is used for a programmed state.

In another example, each memory cell of the MLC may store two bits of data, and has four possible memory states, i.e., a first memory state, a second memory state, a third memory state, and a fourth memory state. The first memory state (for example, “11”) corresponds to a first threshold voltage range, the second memory state (for example, “01”) corresponds to a second threshold voltage range, the third memory state (for example, “10”) corresponds to a third threshold voltage range, and the fourth memory state (for example, “00”) corresponds to a fourth threshold voltage range. In this way, the fourth memory state (for example, “00”) is used for an erased state, and the first memory state (for example, “11”), the second memory state (for example, “01”), and the third memory state (for example, “10”) are used for programmed states.

Similarly, each memory cell of the TLC may store three bits of data, and has eight possible memory states. The eight memory states respectively correspond to eight threshold voltage ranges, and specific memory states are not described herein again. One of the eight threshold voltage ranges is used for an erased state (for example, “111”), and the remaining seven threshold voltage ranges are used for programmed states. In addition, each memory cell of the QLC may store four bits of data, and has sixteen possible memory states. The sixteen memory states respectively correspond to sixteen threshold voltage ranges, and specific memory states are not described herein again. One of the sixteen threshold voltage ranges is used for an erased state (for example, “1111”), and the remaining fifteen threshold voltage ranges are used for programmed states.

Continuously referring to FIG. 4, the above-mentioned peripheral circuit 62 may be coupled to the memory cell array 61 through Bit Lines (BL), Word Lines (WL), source lines, Source Select Gates (SSG), and Drain Select Gates (DSG). The peripheral circuit 62 is configured to apply at least one of a voltage signal or a current signal to each target memory cell through the bit lines BL, the word lines WL, the source lines SL, the source select gates SSG or the drain select gates DSG, etc., and sense at least one of the voltage signal or the current signal from each target memory cell, so as to achieve logical operations (for example, program, read or write operations) of the memory cell array 61.

In an example, the peripheral circuit 62 comprises various types of circuit structures formed by using Metal-Oxide-Semiconductor (MOS) transistors. For example, as shown in FIG. 5, the peripheral circuit 62 may comprise various circuit structures such as a row decoder/word line driver 620, a Page Buffer (PB)/sense amplifier 621, a column decoder/bit line driver 623, a voltage generator 624, a control logic unit 625, a latch circuit 626, an interface 627, and a data bus 628.

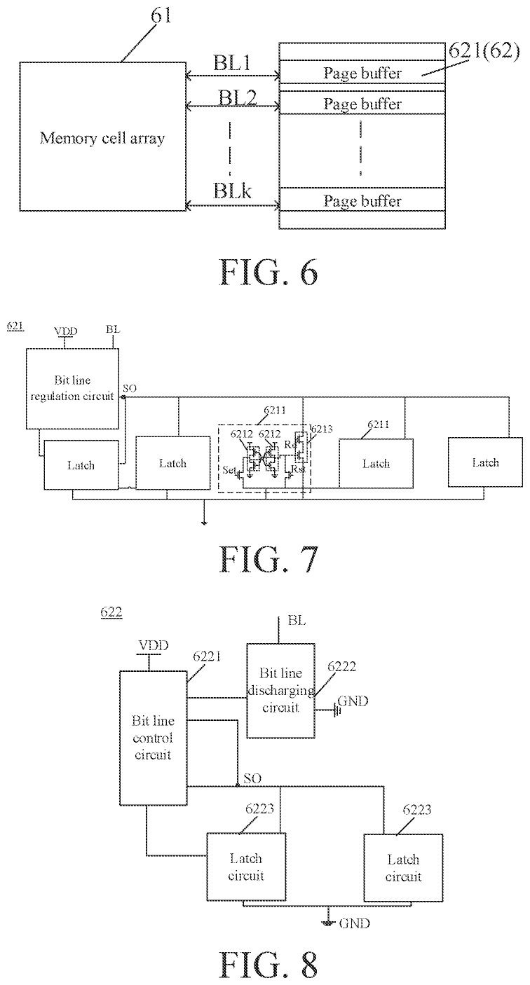

Furthermore, as shown in FIG. 6, the peripheral circuit 62 may comprise a page buffer group constituted by the plurality of page buffers 621. The page buffer group may be coupled with the memory cell array 61 via the plurality of bit lines (BL1 to BLk). One page buffer 621 is coupled with the memory cell array 61 via one bit line. For example, as shown in FIG. 6, the plurality of page buffers 621 may be respectively coupled with the memory cell array 61 via the corresponding bit lines BL1 to BLk.

Based on the above-mentioned content, in some examples, the page buffer 621 of the peripheral circuit 62 comprises a plurality of latches 6211. In an example, as shown in FIG. 7, the page buffer 621 of the peripheral circuit 62 comprises at least five latches 6211.

The latch 6211 comprises two inverters 6212 connected head to tail, a data transmission circuit 6213, and other electronic elements. The two inverters 6212 comprise at least four transistors. In this way, when the page buffer 621 comprises the plurality of latches 6211, especially for TLC and QLC type cells, the page buffer 621 needs to be provided with more latches 6211 to achieve data reading or programming, and there are more transistors in each page buffer 621. Furthermore, when the peripheral circuit 62 achieves the logical operations (for example, program, read or write operations) through the page buffer group (referring to FIG. 6), the number of the electronic elements of the plurality of page buffers 621 is superimposed, leading to a sudden increase in a space occupied by the peripheral circuit 62 in the memory device 60 (for example, occupies nearly ⅓ of the space in the memory device 60), such that an energy efficiency ratio of the memory device 60 is reduced.

In order to solve the above-mentioned problem, as shown in FIGS. 8-21, the present application provides a structure of a page buffer 622, so as to simplify a circuit structure, and reduce a space occupied by the page buffer 622 in the memory device 60 and the manufacturing costs.

In some examples, as shown in FIG. 8, the page buffer 622 comprises a bit line control circuit 6221, a bit line discharging circuit 6222, and a plurality of latch circuits 6223.

The bit line control circuit 6221 is connected with a supply voltage node VDD, a bit line BL, and the sense node SO, and is configured to control a potential level of the sense node SO based on a current level of the bit line BL during a sense operation. For example, whether to charge the bit line may be determined according to a program verify result latched in the latch circuit 6223. For example, when the program verify result indicates that the memory cells have reached a target threshold voltage, the bit line BL coupled to the memory cells may be charged to an inhibit program bit line voltage (e.g., VDD) through the bit line control circuit 6221, so as to inhibit programming; and when the program verify result indicates that the memory cells do not reach the target threshold voltage, the bit line BL coupled to the memory cells may be regulated to a normal program bit line voltage (e.g., VSS) or a bit line BL force voltage (greater than VSS and less than VDD) through the bit line control circuit 6221, so as to continue programming.

The bit line discharging circuit 6222 is connected between the bit line BL and a ground voltage node GND, and is configured to discharge a potential level of the bit line BL in response to a discharging control signal (e.g., VDD).

It can be understood that a level of the above-mentioned supply voltage node VDD is VDD, a level of the ground voltage node GND is VSS, and an identification symbol of the “node” employed in the examples of the present application only characterizes the characteristics of the node transmitting a level signal, and is not intended to limit a magnitude of an actual level signal transmitted by the node.

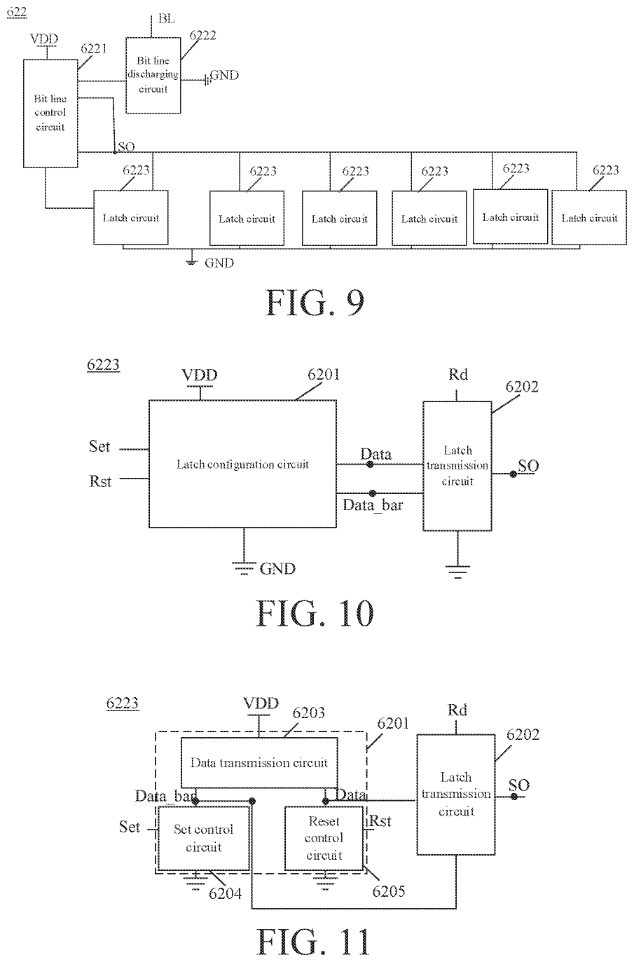

The plurality of latch circuits 6223 are all connected with the sense node SO, and the level of the sense node SO is charged and discharged under the driving of the bit line control circuit 6221 and the bit line discharging circuit 6222. For example, in the page buffer 622 shown in FIG. 9, the number of the plurality of latch circuits 6223 is six. The six latch circuits 6223 may comprise a Sense Latch (S Latch), a Low Voltage Latch (LVT Latch), three Data Latches (D Latch), and a Cache Latch (C Latch).

The sense latch (S Latch) may be configured to store inhibition information and verification information from a verify operation.

The cache latch (C Latch) is configured to perform data exchange with the peripheral, for example, external data is first transmitted into the cache latch (C Latch), and then transmitted into the sense latch (S Latch) through the cache latch (C Latch). For another example, the data in the sense latch (S Latch) is transmitted into the cache latch (C Latch), and then transmitted to the peripheral through the cache latch (C Latch). The peripheral may be the memory controller 31 or the host 20, etc. For yet another example, the cache latch (C Latch) may also be used for other functions, for example, for temporarily storing the verification information.

The data latch (D Latch) may be configured to latch data of a designated page of a memory cell.

The low voltage latch (LVT Latch) may be configured to store the inhibition information and the regulated verification information from the verify operation.

In some examples, the storage type of the memory cell comprises storage types such as SLC, MLC, TLC, QLC, etc.

If the memory cell is the SLC, the latch circuit 6223 in the page buffer 622 may comprise a cache latch. The cache latch is configured to store data of the memory cell.

If the memory cell is the MLC, in addition to the cache latch (C Latch), the page buffer 622 may further comprise a data latch (D Latch). The data latch (D Latch) may be configured to latch data of a lower page of the memory cell, and the cache latch (C Latch) may be configured to latch data of a upper page of the memory cell.

If the memory cell is the TLC, in addition to the cache latch (C Latch), the page buffer 622 may further comprise two data latches (D Latch). One data latch (D Latch) may be configured to latch the data of the lower page of the memory cell, and the other data latch (D Latch) may be configured to latch data of a middle page of the memory cell; and the cache latch (C Latch) may be configured to latch the data of the upper page of the memory cell.

And so on, if the memory cell is a nLC, the number of the data latches (D Latch) in the page buffer 622 may be n−1, the n−1 data latches (D Latch) latch the data of the designated pages of the memory cell respectively, wherein n is a positive integer greater than 0.

It can be understood that the sense latch (S Latch), the low voltage latch (LVT Latch), the data latch (D Latch), and the cache latch (C Latch) comprise subcircuits with partially identical structures, and the subcircuits with partially identical structures can realize complete data transmission. The sense latch (S Latch) and the cache latch (C Latch) further comprise additional electronic elements to assist in realization of data transmission, and the present application imposes no limitations to structures of the additional electronic elements. In the following examples, partially identical circuit structures of different types of the latch circuits 6223 are described, such that the latch circuit 6223 mentioned in the following examples does not limit the type of the latch circuit 6223.

In some examples, as shown in FIG. 10, each latch circuit 6223 comprises a latch control configuration circuit 6201 and a latch transmission circuit 6202.

The latch control configuration circuit 6201 is connected with a first data node (Data) and a second data node (Data_bar), and is configured to: configure the first data node (Data) and the second data node (Data_bar) to different logic levels respectively in response to a configuration signal, wherein a logic level of the first data node (Data) is opposite to a logic level of the second data node (Data_bar).

In some examples, as shown in FIG. 10, the “configuration signal” comprises a set signal (set) transmitted by a Set end and a reset signal (rst) transmitted by a Rst end.

In addition, the logic level of the first data node (Data) is high, and the logic level of the second data node (Data_bar) is low. Alternatively, the logic level of the first data node (Data) is low, and the logic level of the second data node (Data_bar) is high. In different timing phases of a circuit, the logic level of the first data node (Data) is different from the logic level of the second data node (Data_bar), as long as the logic level of the first data node (Data) is opposite to the logic level of the second data node (Data_bar), and details are described in following operation methods.

It can be understood that “high level” and “low level” are two types of signals with relative magnitudes of the level signal.

The latch transmission circuit 6202 is connected with the first data node (Data), the second data node (Data_bar), and a sense node SO, and is configured to couple the second data node (Data_bar) with the sense node SO in response to a transmission signal (rd), to transmit a configuration result of the latch control configuration circuit 6201 to the sense node SO.

It is to be noted that, the “configuration result of the latch control configuration circuit 6201” is information on whether to transmit the logic level of the second data node (Data_bar) to the sense node SO to affect a magnitude of a logic level of the sense node SO based on a signal that controls the latch transmission circuit 6202 to be connected with or disconnected from the sense node SO when the transmission signal (rd) is in an enabled state. For example, the logic level of the first data node (Data) is high, the logic level of the second data node (Data_bar) is low, and the latch transmission circuit 6202 is controlled to be disconnected from the sense node SO, such that the logic level of the second data node (Data_bar) cannot be transmitted to the sense node SO, and the logic level of the sense node SO remains unchanged. Alternatively, when the transmission signal (rd) is in the enabled state, the logic level of the first data node (Data) is low, the logic level of the second data node (Data_bar) is high, and the latch transmission circuit 6202 is controlled to be connected with the sense node SO, such that the logic level of the second data node (Data_bar) can be transmitted to the sense node SO, and the logic level of the sense node SO changes to a high level of the second data node (Data_bar).

The transmission signal (rd) is a signal transmitted by an Rd end. For ease of understanding, an identifier of a signal end provided in the examples of the present application and an identification symbol of a signal transmitted by the signal end are distinguished through initial cases, and the same is true for identifiers of signals such as the set signal (set), the reset signal (rst), a prech_sel_en signal, a prech_all_en signal, a data set signal rst_sa_latch, etc. mentioned in the following examples (correspondingly referring to FIGS. 16 and 20).

In the present application, the latch control configuration circuit 6201 in the page buffer 622 is connected with the first data node (Data) and the second data node (Data_bar), and whether the latch transmission circuit 6202 is connected with or disconnected from the sense node SO is controlled according to the logic levels of the first data node (Data) and the second data node (Data_bar).

In this way, in the case where the latch control configuration circuit 6201 and the latch transmission circuit 6202 do not need to be connected to a ground voltage node GND (for example, in FIG. 7, the inverter 6212 is grounded, and the data transmission circuit 6213 is grounded), not only is the line structure for grounding reduced, but also the number of electronic components (e.g., transistors) is reduced without the use of an inverter 6212, and the cost of fabricating the page buffer 622 and the footprint of the page buffer 622 in the memory device 60 are reduced. In particular, in the case where the memory device 60 includes a page buffer group or includes a page buffer 622 for driving multi-level type of memory cells, it is possible to significantly reduce the cost of fabricating of the page buffer 622 and the footprint of the page buffer 622.

Moreover, the simplified circuit structure reduces the complexity of the signal transmission path between the page buffer 622 and the sense node SO, reduces the loss during the transmission of the level signals, and thus improves the performance of the memory device 60 as a whole.

Moreover, when an area occupied by the page buffer 622 remains unchanged, more latch circuits 6223 may be disposed (for example, adding a data latch circuit 6223), so as to meet requirements of the memory device 60 for higher bits of data, such that more bits of data information may be stored, and the bit density of the memory device 60 is improved.

In some examples, continuously referring to FIG. 10, the latch control configuration circuit 6201 is configured to: set the first data node (Data) and the second data node (Data_bar) to a first logic level and a second logic level respectively in response to a set signal (set) being in an enabled state; and initialize the first data node (Data) and the second data node (Data_bar) to the second logic level and the first logic level respectively in response to a reset signal (rst) being in the enabled state, wherein the first logic level is higher than the second logic level

It can be understood that the first logic level is high, and the second logic level is low. For example, the first logic level is VDD, and the second logic level is VSS.

Continuously referring to FIG. 10, the latch transmission circuit 6202 is configured to: connect the second data node (Data_bar) with the sense node SO when the sense node SO is at the second logic level and in response to the transmission signal (rd) being in the enabled state and the first data node (Data) and the second data node (Data_bar) being at the second logic level and the first logic level respectively, to cause the sense node SO to change from the second logic level to the first logic level.

Alternatively, the latch transmission circuit 6202 is further configured to: maintain the sense node SO at the second logic level when the sense node SO is at the second logic level and in response to the transmission signal (rd) being in the enabled state and the first data node (Data) and the second data node (Data_bar) being at the first logic level and the second logic level respectively.

The above-mentioned latch control configuration circuit 6201 and the latch transmission circuit 6202 charges or discharges the level of the sense node SO in response to different signals in different phases during a driving process of the page buffer 622, a particular signal transmission process is described in an operation method of the page buffer 622 in the following examples.

In some examples, as shown in FIG. 11, the latch control configuration circuit 6201 comprises a data transmission circuit 6203, a set control circuit 6204, and a reset setting control circuit 6205.

The data transmission circuit 6203 is connected with a supply voltage node VDD, the first data node (Data), and the second data node (Data_bar), and is configured to cause the logic level of the first data node (Data) to be opposite to the logic level of the second data node (Data_bar).

The set control circuit 6204 is connected with the second data node (Data_bar) and the ground voltage node GND, and is configured to receive the set signal (set), and control the second data node (Data_bar) to be connected with or disconnected from the ground voltage node GND according to a level of the set signal (set).

The reset setting control circuit 6205 is connected with the first data node (Data) and the ground voltage node GND, and is configured to receive the reset signal, and control the first data node (Data) to be connected with or disconnected from the ground voltage node GND according to a level of the reset signal (rst).

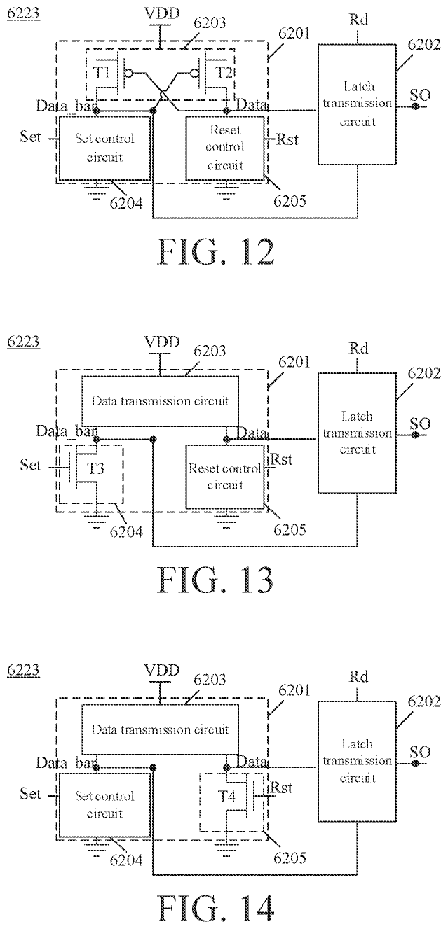

In some examples, as shown in FIG. 12, the data transmission circuit 6203 comprises a first transistor T1 and a second transistor T2.

A control electrode of the first transistor T1 is connected with the first data node (Data), a first electrode of the first transistor T1 is connected with the supply voltage node VDD, and a second electrode of the first transistor T1 is connected with the second data node (Data_bar). A control electrode of the second transistor T2 is connected with the second data node (Data_bar), a first electrode of the second transistor T2 is connected with the supply voltage node VDD, and a second electrode of the second transistor T2 is connected with the first data node (Data).

In an example, continuously referring to FIG. 12, the first transistor T1 and the second transistor T2 are P-type transistors.

In some examples, as shown in FIG. 13, the set control circuit 6204 comprises a third transistor T3. A control electrode of the third transistor T3 is configured to receive the set signal (set), a first electrode of the third transistor T3 is connected with the ground voltage node GND, and a second electrode of the third transistor T3 is connected with the second data node (Data_bar).

As shown in FIG. 14, the reset setting control circuit 6205 comprises a fourth transistor T4. A control electrode of the fourth transistor T4 is configured to receive the reset signal (rst), a first electrode of the fourth transistor T4 is connected with the ground voltage node GND, and a second electrode of the fourth transistor T4 is connected with the first data node (Data).

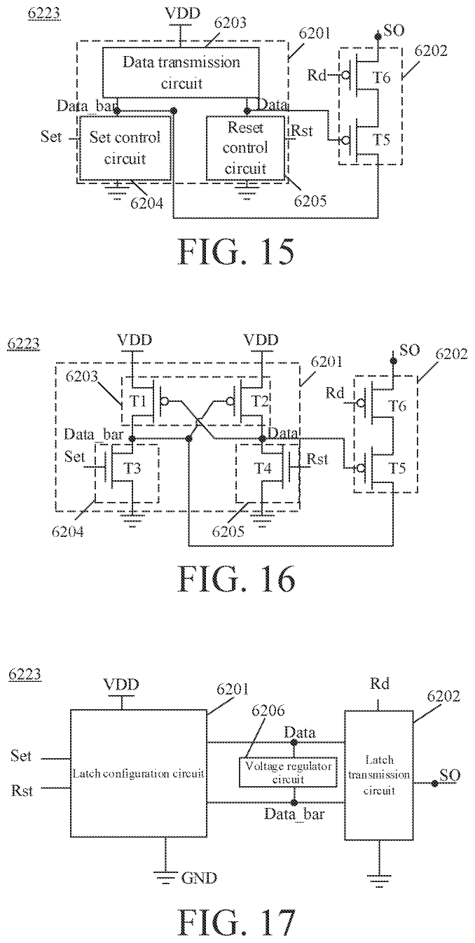

In some examples, as shown in FIG. 15, the latch transmission circuit 6202 comprises a fifth transistor T5 and a sixth transistor T6 connected in series.

A control electrode of the fifth transistor T5 is connected with the first data node (Data), a second electrode of the fifth transistor T5 is connected with the second data node (Data_bar), and a first electrode of the fifth transistor T5 is connected with a second electrode of the sixth transistor T6. A control electrode of the sixth transistor T6 is configured to receive the transmission signal (rd), and a first electrode of the sixth transistor T6 is connected with the sense node SO.

In an example, continuously referring to FIG. 15, the fifth transistor T5 and the sixth transistor T6 are P-type transistors. In this way, considering the nature of P-type transistors that turn on under the control of a low level signal, in order to solve the problem that the level signal received at the control electrode of the transistor cannot turn on the transistor or a turn-on degree of the transistor is relatively poor (i.e., a magnitude relationship between a voltage difference between the control electrode and the first electrode and a threshold voltage is represented as the turn-on degree) caused by reduction of losses generated during transmission of the level signal in a circuit signal line, in a circuit structure for transmitting the level signal between the latch circuit 6223 and the sense node SO, the probability of adverse effects caused by the problem can be reduced by employing the P-type transistors.

In an example, at least two latch circuits 6223 share one latch transmission circuit 6202. For example, two latch circuits 6223 share one latch transmission circuit 6202. In this way, less area is occupied by the structure of the page buffer 622, such that an area of the memory device 60 can be further reduced, so as to realize a high integration level and small size of the memory device 60.

Based on a structure of the latch circuit 6223 provided by the above-mentioned examples, as shown in FIG. 16, the latch circuit 6223 comprises 6 transistors. In combination with a structure of a latch 6211 shown in FIG. 7, two transistors are reduced in the latch circuit 6223 of the present application, such that the cost of the page buffer 622 and the space occupied in the memory device 60 are reduced. The transistors with two inverters reduced, peak currents generated by two inverter transmitting signals via the plurality of transistors are reduced, such that the stability of signal transmission of the page buffer 622 is improved.

Furthermore, while charging and discharging operation functions of the sense node SO are realized, the stability of a line between the latch circuit 6223 and the sense node SO to transmit the level signal is improved, and the accuracy of the sense node SO sensing a signal is improved, such that the performance of the page buffer 622 is improved.

In some examples, as shown in FIGS. 17-19, the latch circuit 6223 further comprises a voltage regulator circuit 6206. As shown in FIG. 17, the voltage regulator circuit 6206 is connected with the first data node (Data) and the second data node (Data_bar), and is configured to stabilize a voltage difference between the first data node (Data) and the second data node (Data_bar).

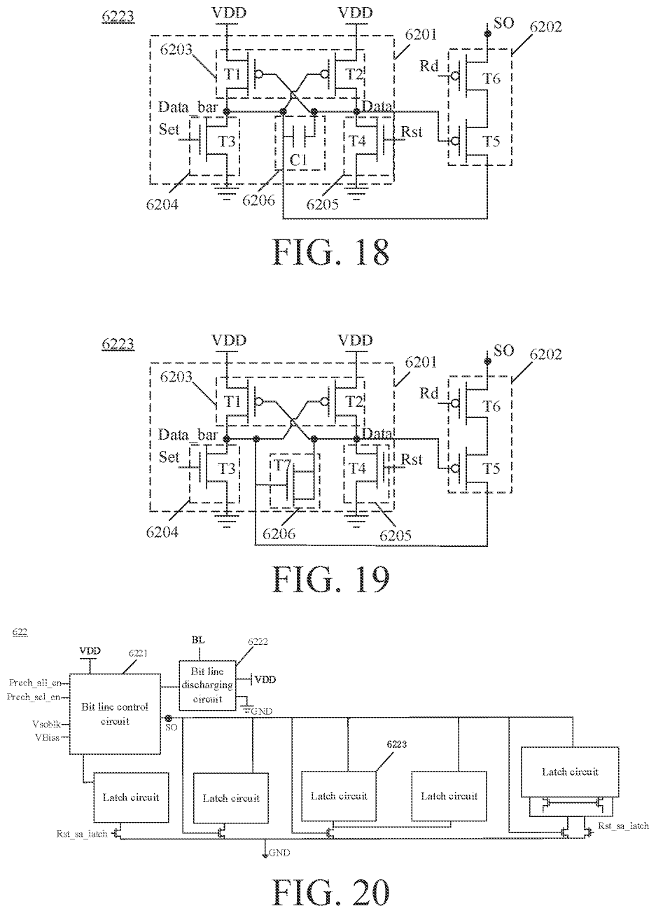

In an example, as shown in FIG. 18, the voltage regulator circuit 6206 comprises a capacitor C1. A first plate of the capacitor C1 is connected with the first data node (Data), and a second plate of a capacitor C2 is connected with the second data node (Data_bar). In this way, the capacitor C1 maintains a voltage difference between the first plate and the second plate stable under a bootstrap function of the capacitor, so as to stabilize the voltage difference between the first data node (Data) and the second data node (Data_bar), such that a voltage difference between the control electrode and first electrode of the fifth transistor T5 is stabilized, that is, a signal flowing through the fifth transistor T5 is guaranteed to be stable.

In an example, as shown in FIG. 19, the voltage regulator circuit 6206 comprises a seventh transistor T7. A control electrode of the seventh transistor T7 is connected with the second data node (Data_bar), a first electrode and second electrode of the seventh transistor T7 both are connected with the first data node (Data). In this way, the first electrode and second electrode of the seventh transistor T7 are connected to the same node (i.e., the first data node (Data)), regardless that the seventh transistor T7 is turned on or turned off under the control of the level signal of the second data node (Data_bar), the level of the first data node (Data) can be maintained to be stable. Then a turn-on degree of the first transistor T1 under the control of the level of the first data node (Data) is stabilized, and the level of the second data node (Data_bar) is stabilized. Therefore, the voltage difference between the control electrode and first electrode of the fifth transistor T5 is stabilized, that is, the signal flowing through the fifth transistor T5 is guaranteed to be stable.

For example, the seventh transistor T7 is an N-type transistor. Considering that a leakage current of the N-type transistor is relatively small, the voltage regulator circuit 6206 employs electronic elements having the N-type transistors, such that the probability of reduction in a voltage regulating effect caused by the leakage current can be reduced.

In addition, the voltage regulator circuit 6206 may also be a circuit comprising other electronic elements having a voltage regulating effect. In an example, the voltage regulator circuit 6206 is a circuit comprising one or more electronic elements in a voltage regulating diode and a linear voltage regulator (such as a low dropout regulator (LDO)). The examples of the present application impose no limitations thereto.

For ease of understanding, based on the page buffer 622 having the latch circuit 6223 provided by the above-mentioned examples, processes of realizing data latching and potential regulation for the sense node SO by the latch circuit 6223 are illustrated as an example. It is to be noted that other latch circuits 6223 in the page buffer 622 may perform similar methods for data set operations.

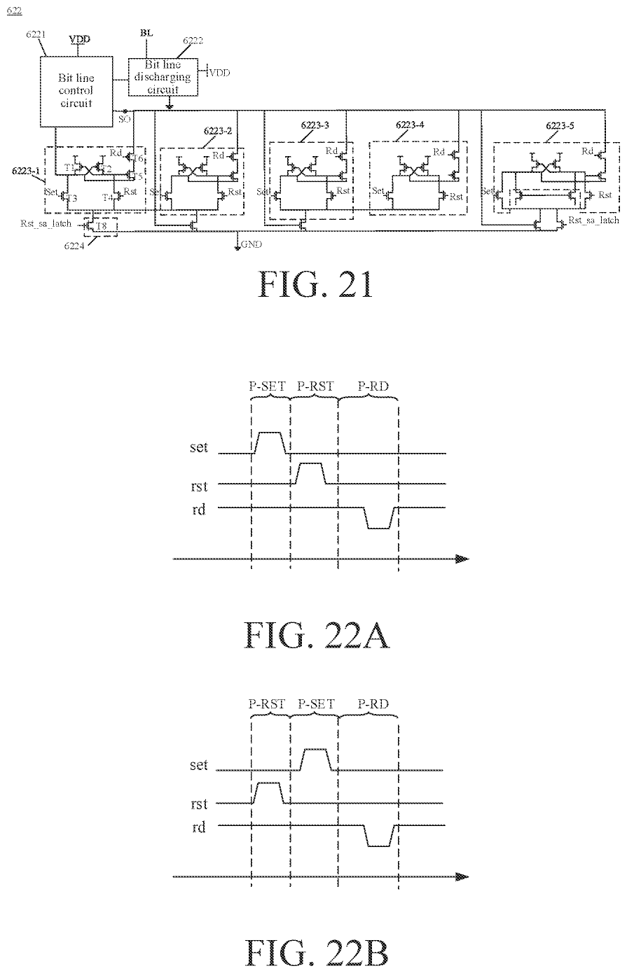

As shown in FIG. 21, the page buffer 622 comprises a bit line control circuit 6221, a bit line discharging circuit 6222, and five latch circuits 6223. The five latch circuits 6223 comprise a sense latch circuit 6223-1, three data latch circuits 6223-2, 6223-3, and 6223-4, and a cache latch circuit 6223-5.

The sense node SO is charged by the bit line control circuit 6221, such that the sense node SO has a high voltage (for example, a supply voltage VDD). Meanwhile, by turning on the third transistor T3 in FIG. 16, a ground voltage from a grounded end may be provided to the second data node (Data_bar) of the sense latch circuit 6223-1, that is, data latched by the sense latch circuit 6223-1 is “1”. Alternatively, by turning on the fourth transistor T4 in FIG. 16, the ground voltage from the grounded end may be transmitted to the first data node (Data) of the sense latch circuit 6223-1, that is, the data latched by the sense latch circuit 6223-1 is “0”.

It is to be noted that, the data “1” may represent a high level or a low level, and the data “0” may represent a low level or a high level. The examples of the present application are described by using the data “1” representing the high level and the data “0” representing the low level as an example.

The sense latch circuit 6223-1 receives the transmission signal (rd) in the enabled state (for example, a rd signal is a low level signal), and the latch transmission circuit 6202 in the sense latch circuit 6223-1 is turned on. If data stored in the sense latch circuit 6223-1 is “1”, the high voltage on the sense node SO may be discharged to a low voltage through the latch transmission circuit 6202; and if the data stored in the sense latch circuit 6223-1 is “0”, the latch transmission circuit 6202 in the sense latch circuit 6223-1 is turned off, such that the high voltage on the sense node SO may not be discharged through the latch transmission circuit 6202, and the voltage on the sense node SO is still the high voltage.

Therefore, data information stored in the sense latch circuit 6223-1 may be obtained by sensing the voltage at the sense node SO at this time. Likewise, data information stored in the corresponding latch circuits 6223 may be obtained through sensing using the corresponding latch circuits 6223.

Moreover, continuously referring to FIG. 21, the page buffer 622 further comprises a data set circuit 6224. The data set circuit 6224 is a force set circuit, that is, when a second data set signal rst_sa_latch is enabled (for example, the rst_sa_latch signal is a high level signal), regardless of the current voltage of the sense node, data set may be performed on the designated latch circuits 6223.

In an example, as shown in FIG. 21, the data set circuit 6224 comprises an eighth transistor T8. A control electrode of the eighth transistor T8 is configured to receive the data set signal rst_sa_latch; a first electrode of the eighth transistor T8 is connected with the latch circuit 6223; and a second electrode of the eighth transistor T8 is connected with the ground voltage node GND.

The eighth transistor T8 includes, but is not limited to, a P-type transistor or an N-type transistor. The examples of the present application is described by taking the N-type transistor as an example of the eighth transistor T8.

In the examples provided by the present application, before the page buffer 622 is enabled, data set or reset operations may be performed on one or more latch circuits 6223 in the page buffer 622 by using the data set circuit 6224. For example, binary data “0” may be used to represent the reset operation, and “1” is used to represent the set operation.

In some examples, the peripheral circuit 62 further comprises a control logic circuit (not shown in FIG. 21). The control logic circuit is connected with the data set circuit 6224 of the page buffer 622, and is configured to generate the data set signal rst_sa_latch. For example, the control logic unit 625 shown in FIG. 5 comprises the control logic circuit.

The control logic circuit may further be configured to generate various control signals required by a page buffer 100, including, but not limited to, the data set signal rst_sa_latch.

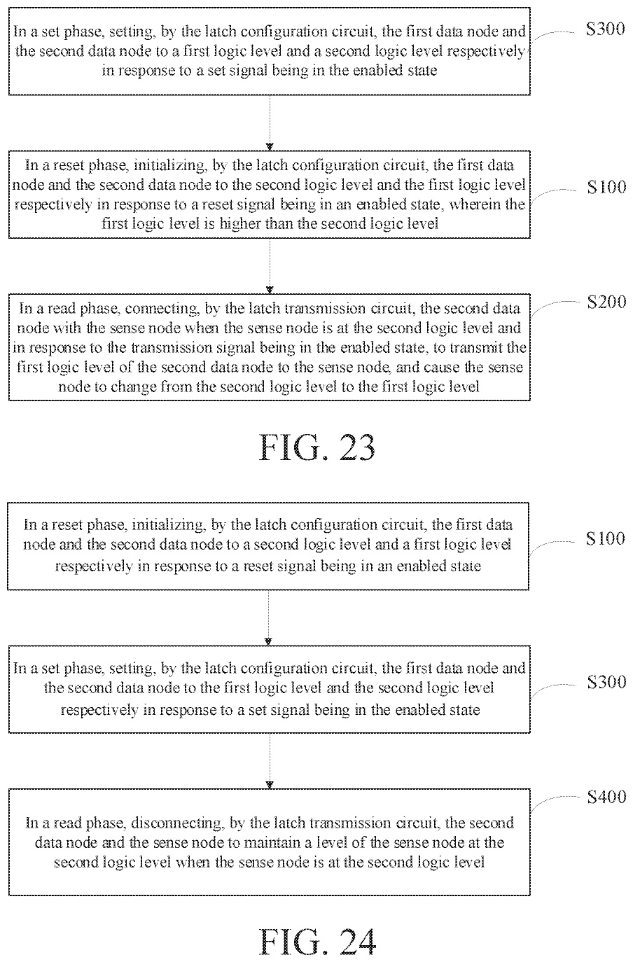

In another aspect, based on the page buffer 622 provided by any one of the above-mentioned examples (referring to FIGS. 8-21), as shown in FIGS. 23 and 24, examples of the present application further provide an operation method of the page buffer 622. The operation method of the page buffer 622 is illustrated in combination with FIGS. 20, 21, 22A, and 22B. Taking the circuit structure shown in FIG. 16 as an example of the latch circuit 6223 of the page buffer 622. The operation method of the page buffer 622 of the present application does not limit all the latch circuits 6223 to be the circuit structure shown in FIG. 16, for example, the latch circuits 6223 may also comprise circuit structures of the voltage regulator circuits 6206 shown in FIGS. 17-19.

As shown in FIGS. 20 and 21, the page buffer 622 comprises the bit line control circuit 6221, the bit line discharging circuit 6222, and the plurality of latch circuits 6223.

The bit line control circuit 6221 is connected with a supply voltage node VDD, a bit line BL, and the sense node SO, and is configured to control a potential level of the sense node SO based on a current level of the bit line BL during a sense operation.

In an example, the bit line control circuit 6221 may set a voltage at the sense node SO according to data latched in the latch circuits 6223, and may also directly set, in response to level signals at a Prech_all_en end and a Prech_sel_en end being in an enabled state, the voltage at the sense node SO based on the supply voltage VDD provided by the supply voltage node VDD. For example, when a signal transmitted at the Prech_all_en end and a signal transmitted at the Prech_sel_en end are simultaneously enabled, a supply voltage (e.g., VDD) may be applied to the sense node SO by the bit line control circuit 6221.

In an example, in a process of programming memory cells, an inhibit program bit line voltage (e.g., VDD) or a normal program bit line voltage (e.g., VSS) may be applied to a bit line BL connected to the memory cells through the bit line control circuit 6221. In an example, a high level is applied to the bit line through a charging function of the bit line control circuit 6221, so as to achieve an effect of inhibiting programming, or the bit line is discharged through a discharging function of the bit line control circuit 6221, such that a voltage of the bit line is pulled down to the ground voltage, so as to achieve an effect of allowing programming, wherein the normal program bit line voltage <the inhibit program bit line voltage.

The bit line discharging circuit 6222 is connected between the bit line BL and the ground voltage node GND, and is configured to discharge a potential level of the bit line BL in response to a discharging control signal prech all_en.

In an example, the bit line discharging circuit 6222 may be a combination of at least one of the plurality of N-type transistors or P-type transistors. Alternatively, the bit line discharging circuit 6222 comprises components for clamping or regulating voltages, for example, one or more components of Zener diodes, transient voltage suppressors, piezoresistors, etc. In an example, the bit line discharging circuit 6222 may generate different bit line force voltages, for example, a first bit line force voltage and a second bit line force voltage, based on different electronic components, wherein the normal program bit line voltage <the first bit line force voltage <the second bit line force voltage <the inhibit program bit line voltage.

In this way, different bit line force voltages can be applied to the bit line BL by using the bit line discharging circuit 6222, so as to realize refined programming of the memory cell, such that distribution of target threshold voltages is narrower, and a read window between the memory cells of different program states is enlarged, thereby guaranteeing accurate reading of data.

The plurality of latch circuits 6223 are connected with the sense node SO, and the level of the sense node SO is charged and discharged under the driving of the bit line control circuit 6221 and the bit line discharging circuit 6222. As shown in FIG. 10, each latch circuit 6223 comprises the latch control configuration circuit 6201 disposed between the first data node (Data) and the second data node (Data_bar), and the latch transmission circuit 6202 connected with the first data node (Data), the second data node (Data_bar), and the sense node SO.

In some examples, as shown in FIG. 20, in the bit line control circuit 6221, when the prech_sel_en signal and the prech_all_en signal are simultaneously enabled, the supply voltage (VDD) may be directly applied to the sense node SO.

In this case, the second transistor T2 in the latch circuit 6223 is turned off. By coupling the latch circuit 6223 with the ground voltage node GND through the data set circuit 6224, and under the action of both the first transistor T1 and the second transistor T2 (i.e., the fifth transistor T5 is turned on), the latch circuit 6223 is coupled with the sense node SO in response to the rd signal being enabled, to discharge the level of the sense node SO. In this way, when a vbias signal and a vsoblk signal are simultaneously enabled, a level signal of the sense node SO is fed back to the bit line BL. The bit line BL obtains the data latched by the latch circuit 6223 by reading the level of the sense node SO.

Alternatively, continuously referring to FIG. 20, when the prech_sel_en signal is in an enabled state and the prech_all_en signal is in a non-enabled state, the bit line control circuit 6221 applies the supply voltage (VDD) to the sense node SO in response to a signal transmitted by the latch circuit 6223.

In this case, the second transistor T2 in the latch circuit 6223 is turned on. By coupling the latch circuit 6223 with the ground voltage node GND through the data set circuit 6224, and under the action of both the first transistor T1 and the second transistor T2 (i.e., the fifth transistor T5 is turned off), the latch circuit 6223 does not discharge the level of the sense node SO.

Then when the bit line control circuit 6221 couples the bit line BL to the sense node SO in response to the vbias signal and the vsoblk signal both being enabled, the bit line BL obtains the data latched by the latch circuit 6223 by reading the level of the sense node SO.

In order to embody a driving process of the latch circuit 6223 of the page buffer 622 more clearly, in combination with timing diagrams shown in FIGS. 22A and 22B, the above-mentioned operations are described in detail below by taking the latch circuit 6223 shown in FIG. 16 as an example.

As shown in FIG. 16, the latch circuit 6223 comprises the latch control configuration circuit 6201 and the latch transmission circuit 6202. The latch control configuration circuit 6201 comprises the data transmission circuit 6203, the set control circuit 6204, and the reset setting control circuit 6205.

The data transmission circuit 6203 comprises the first transistor T1 and the second transistor T2. The first transistor T1 and the second transistor T2 both are P-type transistors.

The set control circuit 6204 comprises the third transistor T3. The third transistor T3 is an N-type transistor.

The reset setting control circuit 6205 comprises the fourth transistor T4. The fourth transistor T4 is an N-type transistor.

The latch transmission circuit 6202 comprises the fifth transistor T5 and the sixth transistor T6 connected in series. The fifth transistor T5 and the sixth transistor T6 both are P-type transistors.

Based on this, as shown in FIGS. 23 and 24, the operation method at least comprises S100, S200, S300, and S400. As shown in FIGS. 22A and 22B, an operation process of the page buffer 622 comprises three phases, i.e., a set phase P-SET, a reset phase P-RST, and a read phase P-RD. In addition, the timing diagrams provided by FIGS. 22A and 22B only show signals employed in a driving process of the latch circuit 6223, and different phases may have a certain degree of time intervals, and may also be adjacent, to which the present application imposes no limitations.

Meanwhile, in order to embody the characteristics of the latch circuit 6223, that is, in different phases, in response to configuration signals with opposite logic levels (for example, the set signal (set) and the reset signal (rst) have opposite logic levels in the same phase), the latch circuit 6223 causes the logic level of the first data node (Data) and the logic level of the second data node (Data_bar) connected with the latch control configuration circuit 6201 to be opposite.

In an example, as shown in FIG. 22A, a previous phase of the read phase P-RD may be the reset phase P-RST, and the logic levels of the first data node (Data) and the second data node (Data_bar) obtained in the reset phase P-RST are a set of target levels. Based on the characteristics of the latch circuit 6223, before the reset phase P-RST, there have to be a process (e.g., the set phase P-SET) of causing the logic levels of the first data node (Data) and the second data node (Data_bar) to be opposite to the set of target levels.

In an example, as shown in FIG. 22B, the previous phase of the read phase P-RD may also be the set phase P-SET, and the logic levels of the first data node (Data) and the second data node (Data_bar) obtained in the set phase P-SET are a set of target levels. Based on the characteristics of the latch circuit 6223, before the set phase P-SET, there have to be a process (e.g., the reset phase P-RST) of causing the logic levels of the first data node (Data) and the second data node (Data_bar) to be opposite to the set of target levels.

In addition, considering that states of the plurality of latch circuits 6223 in different page buffers 622 may be the same or different, for example, a part of the latch circuits 6223 performs a data write operation, and the other part of the latch circuits 6223 performs an operation of actively transmitting data. That is to say, data read in the read phase P-RD is data latched in a previous phase (the set phase P-SET or the reset phase P-RST) of a current state of the latch circuit 6223. In this way, within the same time period, signals transmitted by different latch circuits 6223 are different, and the data read in the read phase P-RD is different.

Therefore, as shown in FIGS. 22A and 22B, in the same timing process, two sequences of the set phase P-SET and the reset phase P-RST are embodied.

In order to clearly distinguish between different operation methods of acquiring data by different latch circuits 6223 in the read phase P-RD, two operation methods shown in FIGS. 22A and 23 and FIGS. 22B and 24 are used as examples for description.

In some examples, as shown in FIGS. 22A and 23, the operation process of the page buffer 622 comprises the set phase P-SET, the reset phase P-RST after the set phase P-SET, and the read phase P-RD after the reset phase P-RST.

In an example, as shown in FIGS. 16, 22A, and 23, the operation method comprises S300, S100, and S200.

S300: in a set phase P-SET, setting, by the latch control configuration circuit 6201, the first data node (Data) and the second data node (Data_bar) to a first logic level and a second logic level respectively in response to a set signal (set) being in the enabled state, wherein the first logic level is higher than the second logic level.

In an example, continuously referring to FIGS. 16 and 22A, a pre-charging operation is performed on the sense node SO, such that the sense node SO has the first logic level. For example, the first logic level is VDD.

The third transistor T3 of the set control circuit 6204 is turned on in response to the set signal being in the enabled state, to couple the ground voltage node GND with the second data node (Data_bar), and transmit the second logic level to the control electrode of the second transistor T2 in the data transmission circuit 6203. The second transistor T2 is turned on to transmit the first logic level of the supply voltage node VDD to the first data node (Data). In this case, the fourth transistor T4 of the reset setting control circuit 6205 is turned off in response to the reset signal (rst), and the level of the first data node (Data) is maintained at the first logic level.

Meanwhile, the first transistor T1 in the data transmission circuit 6203 is turned off in response to the first logic level of the first data node (Data), and the level of the second data node (Data_bar) is maintained at the second logic level. For example, the second logic level is VSS.

In this way, the fifth transistor T5 of the latch transmission circuit 6202 is turned off in response to the level signal of the first data node (Data). The latch circuit 6223 is disconnected from the sense node SO, and the sense node SO is maintained at the first logic level.

S100: in a reset phase P-RST, initializing, by the latch control configuration circuit 6201, the first data node (Data) and the second data node (Data_bar) to the second logic level and the first logic level respectively in response to a reset signal (rst) being in an enabled state.

In an example, continuously referring to FIGS. 16 and 22A, the reset setting control circuit 6205 responds to the reset signal (rst) being in the enabled state, the fourth transistor T4 of the reset setting control circuit 6205 is turned on, such that a level of the ground voltage node GND is transmitted to the first data node (Data), and the level of the first data node (Data) is set to the second logic level.

The first transistor T1 of the data transmission circuit 6203 is turned on in response to the second logic level of the first data node (Data), to transmit a level of the supply voltage node VDD to the second data node (Data_bar), and the level of the second data node (Data_bar) is set to the first logic level. The first logic level is higher than the second logic level. For example, the first logic level is VDD, and the second logic level is VSS.

Meanwhile, the third transistor T3 of the set control circuit 6204 is turned off in response to the set signal (set) being in the non-enabled state, and the level of the second data node (Data_bar) is maintained at the first logic level.

In this way, the fifth transistor T5 of the latch transmission circuit 6202 is turned on in response to the second logic level of the first data node (Data). Since the sixth transistor T6 is turned off in response to the transmission signal (rd) being in the non-enabled state, the latch circuit 6223 is disconnected from the sense node SO, and the sense node SO is maintained at the first logic level.

Based on the above-mentioned operation process, the level of the sense node SO is the first logic level. A programming operation is performed on the latch circuit 6223 through the bit line BL, and the latch circuit 6223 latches target data. Data read in the following read phase P-RD is data set in the reset phase P-RST.

S200: in a read phase P-RD after the reset phase P-RST, connecting, by the latch transmission circuit 6202, the second data node (Data_bar) with the sense node SO when the sense node SO is at the second logic level and in response to the transmission signal (rd) being in the enabled state, to transmit the first logic level of the second data node (Data_bar) to the sense node SO, and cause the sense node SO to change from the second logic level to the first logic level.

In an example, the level of the sense node SO is first discharged to the second logic level.

Continuously referring to FIGS. 16 and 22A, after S100, the first data node (Data) has the second logic level, and the second data node (Data_bar) has the first logic level. The fifth transistor T5 of the latch transmission circuit 6202 is turned on in response to the second logic level of the first data node (Data); and the sixth transistor T6 is turned on in response to the transmission signal (rd), to connect the second data node (Data_bar) with the sense node SO. Therefore, the first logic level of the second data node (Data_bar) is transmitted to the sense node SO.

In this way, the sense node SO changes from the second logic level to the first logic level. That is to say, data of the latch circuit 6223 is read through the bit line BL. Then the data read is latched into other latch circuits 6223 through the bit line BL (for example, S300 and S100 in the method mentioned above).

In some other examples, as shown in FIGS. 22B and 24, the operation process of the page buffer 622 comprises the reset phase P-RST, the set phase P-SET after the reset phase P-RST, and the read phase P-RD after the set phase P-SET.

In an example, as shown in FIGS. 16, 22B, and 24, the operation method comprises S100, S300, and S400.

S100: in a reset phase P-RST, initializing, by the latch control configuration circuit 6201, the first data node (Data) and the second data node (Data_bar) to the second logic level and the first logic level respectively in response to a reset signal (rst) being in an enabled state, wherein the first logic level is higher than the second logic level.

In an example, continuously referring to FIGS. 16 and 22B, the reset setting control circuit 6205 responds to the reset signal (rst) being in the enabled state, the fourth transistor T4 of the reset setting control circuit 6205 is turned on, such that a level of the ground voltage node GND is transmitted to the first data node (Data), and the level of the first data node (Data) is set to the second logic level.

The first transistor T1 of the data transmission circuit 6203 is turned on in response to the second logic level of the first data node (Data), to transmit a level of the supply voltage node VDD to the second data node (Data_bar), and the level of the second data node (Data_bar) is set to the first logic level. The first logic level is higher than the second logic level. For example, the first logic level is VDD, and the second logic level is VSS.

Meanwhile, the third transistor T3 of the set control circuit 6204 is turned off in response to the set signal (set) being in the non-enabled state, and the level of the second data node (Data_bar) is maintained at the first logic level.

In this way, the fifth transistor T5 of the latch transmission circuit 6202 is turned on in response to the second logic level of the first data node (Data). Since the sixth transistor T6 is turned off in response to the transmission signal (rd) being in the non-enabled state, the latch circuit 6223 is disconnected from the sense node SO, and the sense node SO is maintained at the first logic level.

S300: in a set phase P-SET, setting, by the latch control configuration circuit 6201, the first data node (Data) and the second data node (Data_bar) to a first logic level and a second logic level respectively in response to a set signal (set) being in the enabled state.

In an example, continuously referring to FIGS. 16 and 22B, the third transistor T3 of the set control circuit 6204 is turned on in response to the set signal being in the enabled state, to couple the ground voltage node GND with the second data node (Data_bar), and transmit the second logic level to the control electrode of the second transistor T2 in the data transmission circuit 6203. The second transistor T2 is turned on to transmit the first logic level of the supply voltage node VDD to the first data node (Data). In this case, the fourth transistor T4 of the reset setting control circuit 6205 is turned off in response to the reset signal (rst), and the level of the first data node (Data) is maintained at the first logic level.

Meanwhile, the first transistor T1 in the data transmission circuit 6203 is turned off in response to the first logic level of the first data node (Data), and the level of the second data node (Data_bar) is maintained at the second logic level.

In this way, the fifth transistor T5 of the latch transmission circuit 6202 is turned off in response to the level signal of the first data node (Data). The latch circuit 6223 is disconnected from the sense node SO, and the sense node SO is maintained at the first logic level.

Based on the above-mentioned operation process, the level of the sense node SO is the first logic level. A programming operation is performed on the latch circuit 6223 through the bit line BL, and the latch circuit 6223 latches target data. Data read in the following read phase P-RD is data set in the set phase P-SET.

S400: in a read phase P-RD after the set phase P-SET, disconnecting, by the latch transmission circuit 6202, the second data node (Data_bar) and the sense node SO to maintain a level of the sense node SO at the second logic level when the sense node SO is at the second logic level.

In an example, the level of the sense node SO is first discharged to the second logic level.

Continuously referring to FIGS. 16 and 22B, after S300, the first data node (Data) has the first logic level, and the second data node (Data_bar) has the second logic level. The fifth transistor T5 of the latch transmission circuit 6202 is turned off in response to the first logic level of the first data node (Data).

Based on this, regardless of the transmission signal (rd) being in the enabled state (i.e., if the rd signal is a high level signal, the sixth transistor T6 is turned off; or if the rd signal is a low level signal, the sixth transistor T6 is turned on), the second data node (Data_bar) is disconnected from the sense node SO, and the level of the sense node SO is maintained at the second logic level. In this way, the bit line BL continues to read the data of the latch circuit 6223 through the sense node SO.

The operation method of a page buffer 622 provided by the present application comprises two processes shown in FIGS. 23 and 24, one is connecting the latch transmission circuit 6202 with the sense node SO in the read phase P-RD when the transmission signal (rd) is in an enabled state based on the level signals stored in the first data node (Data) and the second data node (Data_bar) in the reset phase P-SET, causing the level of the sense node SO to change. The other is disconnecting the latch transmission circuit 6202 and the sense node SO to maintain the level of the sense node SO in the read phase P-RD based on the level signals stored in the first data node (Data) and the second data node (Data_bar) in the set phase P-SET even when the transmission signal (rd) is in the enabled state. The two processes are based on the plurality of latch circuits comprised in different page buffers, wherein different latch circuits may have different states in the same time period, characterized as that in the read phase P-RD of the operation process of the page buffer 622, the data stored in the set phase P-SET is read or, alternatively, the data stored in the reset phase P-SET is read. In this way, during the read phase P-RD, the latch circuits 6223 of different page buffers 622 affect the level of the sense node SO differently, thereby acquiring different data from different page buffers 622 through the sense node SO. The present application provides a circuit structure of the page buffer 622 that can simultaneously realize the reading of data in the memory cells of different states.

In view of this, examples of the present application provide a page buffer and an operation method thereof, a memory device and a memory system.

In an aspect, examples of the present application provide a page buffer, comprising: a plurality of latch circuits, wherein each of the latch circuits comprises: a latch control configuration circuit connected with a first data node and a second data node, and configured to: configure the first data node and the second data node to different logic levels respectively in response to a configuration signal, wherein a logic level of the first data node is opposite to a logic level of the second data node; and a latch transmission circuit connected with the first data node, the second data node, and a sense node, and configured to: couple the second data node with the sense node in response to a transmission signal, to transmit a configuration result of the latch control configuration circuit to the sense node.

In some examples, the latch control configuration circuit is configured to: set the first data node and the second data node to a first logic level and a second logic level respectively in response to a set signal being in an enabled state; and initialize the first data node and the second data node to the second logic level and the first logic level respectively in response to a reset signal being in the enabled state, wherein the first logic level is higher than the second logic level; and

the latch transmission circuit is configured to: connect the second data node with the sense node when the sense node is at the second logic level and in response to the transmission signal being in the enabled state and the first data node and the second data node being at the second logic level and the first logic level respectively, to cause the sense node to change from the second logic level to the first logic level.

In some examples, the latch transmission circuit is further configured to: maintain the sense node at the second logic level when the sense node is at the second logic level and in response to the transmission signal being in the enabled state and the first data node and the second data node being at the first logic level and the second logic level respectively.

In some examples, the latch control configuration circuit comprises: a data transmission circuit connected with a supply voltage node, the first data node, and the second data node, and configured to: cause the logic level of the first data node to be opposite to the logic level of the second data node; a set control circuit connected with the second data node and a ground voltage node, and configured to: receive the set signal, and control the second data node to be connected with or disconnected from the ground voltage node according to a level of the set signal; and a reset setting control circuit connected with the first data node and the ground voltage node, and configured to: receive the reset signal, and control the first data node to be connected with or disconnected from the ground voltage node according to a level of the reset signal.

In some examples, the data transmission circuit comprises a first transistor and a second transistor, wherein a control electrode of the first transistor is connected with the first data node, a first electrode of the first transistor is connected with the supply voltage node, and a second electrode of the first transistor is connected with the second data node, and a control electrode of the second transistor is connected with the second data node, a first electrode of the second transistor is connected with the supply voltage node, and a second electrode of the second transistor is connected with the first data node.

In some examples, the set control circuit comprises a third transistor, wherein a control electrode of the third transistor is configured to receive the set signal, a first electrode of the third transistor is connected with the ground voltage node, and a second electrode of the third transistor is connected with the second data node; and the reset setting control circuit comprises a fourth transistor, wherein a control electrode of the fourth transistor is configured to receive the reset signal, a first electrode of the fourth transistor is connected with the ground voltage node, and a second electrode of the fourth transistor is connected with the first data node.

In some examples, the latch transmission circuit comprises a fifth transistor and a sixth transistor connected in series, wherein the fifth transistor and the sixth transistor are P-type transistors.

In some examples, a control electrode of the fifth transistor is connected with the first data node, a second electrode of the fifth transistor is connected with the second data node, and a first electrode of the fifth transistor is connected with a second electrode of the sixth transistor; and a control electrode of the sixth transistor is configured to receive the transmission signal, and a first electrode of the sixth transistor is connected with the sense node.

In some examples, the latch circuit further comprises a voltage regulator circuit connected with the first data node and the second data node, and configured to stabilize a voltage difference between the first data node and the second data node.

In some examples, the voltage regulator circuit comprises a capacitor, wherein a first plate of the capacitor is connected with the first data node, and a second plate of the capacitor is connected with the second data node.

In some examples, the voltage regulator circuit comprises a seventh transistor, wherein a control electrode of the seventh transistor is connected with the second data node, and a first electrode and second electrode of the seventh transistor both are connected with the first data node.

In some examples, the page buffer further comprises a bit line control circuit and a bit line discharging circuit. The bit line control circuit is connected with a supply voltage node, a bit line, and the sense node, and is configured to: control a potential level of the sense node based on a current level of the bit line during a sense operation. The bit line discharging circuit is connected between the bit line and a ground voltage node, and is configured to: discharge a potential level of the bit line in response to a discharging control signal.

In the present application, the latch control configuration circuit in the page buffer is connected with the first data node and the second data node, and whether the latch transmission circuit is connected with or disconnected from the sense node is controlled according to the logic levels of the first data node and the second data node. In this way, in the case where the latch control configuration circuit and the latch transmission circuit do not need to be connected to a ground voltage node, not only is the line structure for grounding reduced, but also the number of electronic components (e.g., transistors) is reduced without the direct use of an inverter, and the cost of fabricating the page buffer and the footprint of the page buffer in the memory device are reduced. In particular, in the case where the memory device includes a page buffer group or includes a page buffer for driving multi-level type of memory cells, it is possible to significantly reduce the cost of fabricating of the page buffer and the footprint of the page buffer.

Moreover, the simplified circuit structure reduces the complexity of the signal transmission path between the page buffer and the sense node, reduces the loss during the transmission of the level signals, and thus improves the performance of the memory device as a whole.

In another aspect, the present application provides a memory device. The memory device comprises a memory cell array and a plurality of page buffers provided by any one of the above examples. The memory cell array is connected with a plurality of bit lines. Each of the page buffers is connected with one of the bit lines, and is configured to perform a sense operation based on a current level of the bit line.

Beneficial effects achieved by the memory device provided by this example are the same as beneficial effects of the page buffer provided by any one of the above examples, and are not described herein again.

In yet another aspect, the present application provides a memory system. The memory system comprises one or more memory devices provided by the above aspect, and a memory controller. The memory controller is connected with the memory device and is configured to control the memory device.

Beneficial effects achieved by the memory system provided by this example are the same as beneficial effects of the memory device provided by the above-mentioned examples, and are not described herein again.

In a still further aspect, the present application provides an operation method of a page buffer. The page buffer comprises a plurality of latch circuits, wherein each of the latch circuits comprises: a latch control configuration circuit disposed between a first data node and a second data node; and a latch transmission circuit connected with the first data node, the second data node, and a sense node. The operation method comprises the following operations:

in a reset phase, initializing, by the latch control configuration circuit, the first data node and the second data node to a second logic level and a first logic level respectively in response to a reset signal being in an enabled state, wherein the first logic level is higher than the second logic level; and

in a read phase after the reset phase, connecting, by the latch transmission circuit, the second data node with the sense node when the sense node is at the second logic level and in response to the transmission signal being in the enabled state, to transmit the first logic level of the second data node to the sense node, and cause the sense node to change from the second logic level to the first logic level.

In some examples, the operation method further comprises: in a set phase, setting, by the latch control configuration circuit, the first data node and the second data node to the first logic level and the second logic level respectively in response to a set signal being in the enabled state; and

in a read phase after the set phase, disconnecting, by the latch transmission circuit, the second data node and the sense node to maintain a level of the sense node at the second logic level when the sense node is at the second logic level.

The operation method of a page buffer provided by the present application comprises two processes, one is connecting the latch transmission circuit with the sense node in the read phase when the transmission signal is in an enabled state based on the level signals stored in the first data node and the second data node in the reset phase, causing the level of the sense node to change. The other is disconnecting the latch transmission circuit and the sense node to maintain the level of the sense node in the read phase based on the level signals stored in the first data node and the second data node in the set phase even when the transmission signal is in the enabled state. The two processes are based on the plurality of latch circuits comprised in different page buffers, wherein different latch circuits may have different states in the same time period, characterized as that in the read phase of the operation process of the page buffer, the data stored in the set phase is read or, alternatively, the data stored in the reset phase is read. In this way, during the read phase, the latch circuits of different page buffers affect the level of the sense node differently, thereby acquiring different data from different page buffers through the sense node. The present application provides a circuit structure of the page buffer that can simultaneously realize the reading of data in the memory cells of different states.

It is to be understood that, references to “some examples” throughout this specification mean that particular features, structures, or characteristics related to the examples are included in at least one example of the present application. Therefore, “in some examples” appearing everywhere in the entire specification does not refer to the same example. Furthermore, these particular features, structures, or characteristics may be incorporated in one or more examples in any suitable manner. It is to be understood that, in various examples of the present application, sequence numbers of the above processes do not indicate an execution order, and an execution order of various processes shall be determined by functionalities and intrinsic logics thereof, and shall constitute no limitation on an implementation process of the examples of the present application. The above sequence numbers of the examples of the present application are only for description, and do not represent advantages or disadvantages of the examples.

It is to be noted that, the terms “comprise”, “include” or any variants thereof herein are intended to cover non-exclusive inclusion, such that a process, a method, an article or a device comprising a series of elements comprise not only those elements, but also other elements not listed explicitly, or elements inherent to this process, method, article or device. An element defined by a statement “comprising one” do not preclude the presence of another identical element in the process, method, article or device comprising this element, without more limitations.

The above descriptions are merely examples of the present application, but the protection scope of the present application is not limited to these. Any variation or replacement readily figured out by those skilled in the art within the technical scope as disclosed by the present application shall fall within the protection scope of the present application. Therefore, the protection scope of the present application shall be subject to the protection scope of the claims.

What is claimed is:

1. A page buffer, comprising:
a plurality of latch circuits, wherein each of the latch circuits includes:
a latch control configuration circuit connected with a first data node and a second data node, and configured to: configure the first data node and the second data node to different logic levels respectively in response to a configuration signal, wherein a logic level of the first data node is opposite to a logic level of the second data node; and
a latch transmission circuit connected with the first data node, the second data node, and a sense node, and configured to: couple the second data node with the sense node in response to a transmission signal, to transmit a configuration result of the latch control configuration circuit to the sense node.

2. The page buffer of claim 1, wherein
the latch control configuration circuit is configured to:
set the first data node and the second data node to a first logic level and a second logic level respectively in response to a set signal being in an enabled state; and
initialize the first data node and the second data node to the second logic level and the first logic level respectively in response to a reset signal being in the enabled state, wherein the first logic level is higher than the second logic level; and
the latch transmission circuit is configured to:
connect the second data node with the sense node when the sense node is at the second logic level and in response to the transmission signal being in the enabled state and the first data node and the second data node being at the second logic level and the first logic level respectively, to cause the sense node to change from the second logic level to the first logic level.

3. The page buffer of claim 2, wherein the latch transmission circuit is further configured to:
maintain the sense node at the second logic level when the sense node is at the second logic level and in response to the transmission signal being in the enabled state and the first data node and the second data node being at the first logic level and the second logic level respectively.

4. The page buffer of claim 1, wherein the latch control configuration circuit includes:
a data transmission circuit connected with a supply voltage node, the first data node, and the second data node, and configured to:
cause the logic level of the first data node to be opposite to the logic level of the second data node;
a set control circuit connected with the second data node and a ground voltage node, and configured to:
receive a set signal, and control the second data node to be connected with or disconnected from the ground voltage node according to a level of the set signal; and
a reset setting control circuit connected with the first data node and the ground voltage node, and configured to:
receive a reset signal, and control the first data node to be connected with or disconnected from the ground voltage node according to a level of the reset signal.

5. The page buffer of claim 4, wherein the data transmission circuit includes:
a first transistor, wherein a control electrode of the first transistor is connected with the first data node, a first electrode of the first transistor is connected with the supply voltage node, and a second electrode of the first transistor is connected with the second data node; and
a second transistor, wherein a control electrode of the second transistor is connected with the second data node, a first electrode of the second transistor is connected with the supply voltage node, and a second electrode of the second transistor is connected with the first data node.

6. The page buffer of claim 4, wherein
the set control circuit includes a third transistor, wherein a control electrode of the third transistor is configured to receive the set signal, a first electrode of the third transistor is connected with the ground voltage node, and a second electrode of the third transistor is connected with the second data node; and
the reset setting control circuit includes a fourth transistor, wherein a control electrode of the fourth transistor is configured to receive the reset signal, a first electrode of the fourth transistor is connected with the ground voltage node, and a second electrode of the fourth transistor is connected with the first data node.

7. The page buffer of claim 1, wherein the latch transmission circuit includes a fifth transistor and a sixth transistor connected in series, wherein the fifth transistor and the sixth transistor are P-type transistors.

8. The page buffer of claim 7, wherein
a control electrode of the fifth transistor is connected with the first data node, a second electrode of the fifth transistor is connected with the second data node, and a first electrode of the fifth transistor is connected with a second electrode of the sixth transistor; and
a control electrode of the sixth transistor is configured to receive the transmission signal, and a first electrode of the sixth transistor is connected with the sense node.

9. The page buffer of claim 1, wherein the latch circuit further includes:
a voltage regulator circuit connected with the first data node and the second data node, and configured to stabilize a voltage difference between the first data node and the second data node.

10. The page buffer of claim 9, wherein the voltage regulator circuit includes:
a capacitor, wherein a first plate of the capacitor is connected with the first data node, and a second plate of the capacitor is connected with the second data node.

11. The page buffer of claim 9, wherein the voltage regulator circuit includes:
a seventh transistor, wherein a control electrode of the seventh transistor is connected with the second data node, and a first electrode and second electrode of the seventh transistor both are connected with the first data node.

12. The page buffer of claim 1, further including:
a bit line control circuit connected with a supply voltage node, a bit line, and the sense node, and configured to:
control a potential level of the sense node based on a current level of the bit line during a sense operation; and
a bit line discharging circuit connected between the bit line and a ground voltage node, and configured to:
discharge a potential level of the bit line in response to a discharging control signal.

13. A memory device, comprising:
a memory cell array connected with a plurality of bit lines; and
a plurality of page buffers, wherein each of the page buffers is connected with one of the bit lines, and is configured to perform a sense operation based on a current level of the bit line, and each of the page buffers includes:
a plurality of latch circuits, wherein each of the latch circuits includes:
a latch control configuration circuit connected with a first data node and a second data node, and configured to: configure the first data node and the second data node to different logic levels respectively in response to a configuration signal, wherein a logic level of the first data node is opposite to a logic level of the second data node; and
a latch transmission circuit connected with the first data node, the second data node, and a sense node, and configured to: couple the second data node with the sense node in response to a transmission signal, to transmit a configuration result of the latch control configuration circuit to the sense node.

14. The memory device of claim 13, wherein
the latch control configuration circuit is configured to:
set the first data node and the second data node to a first logic level and a second logic level respectively in response to a set signal being in an enabled state; and
initialize the first data node and the second data node to the second logic level and the first logic level respectively in response to a reset signal being in the enabled state, wherein the first logic level is higher than the second logic level; and
the latch transmission circuit is configured to:
connect the second data node with the sense node when the sense node is at the second logic level and in response to the transmission signal being in the enabled state and the first data node and the second data node being at the second logic level and the first logic level respectively, to cause the sense node to change from the second logic level to the first logic level.

15. The memory device of claim 14, wherein the latch transmission circuit is further configured to:
maintain the sense node at the second logic level when the sense node is at the second logic level and in response to the transmission signal being in the enabled state and the first data node and the second data node being at the first logic level and the second logic level respectively.

16. The memory device of claim 13, wherein the latch control configuration circuit includes:
a data transmission circuit connected with a supply voltage node, the first data node, and the second data node, and configured to:
cause the logic level of the first data node to be opposite to the logic level of the second data node;
a set control circuit connected with the second data node and a ground voltage node, and configured to:
receive a set signal, and control the second data node to be connected with or disconnected from the ground voltage node according to a level of the set signal; and
a reset setting control circuit connected with the first data node and the ground voltage node, and configured to:
receive a reset signal, and control the first data node to be connected with or disconnected from the ground voltage node according to a level of the reset signal.

17. The memory device of claim 16, wherein the data transmission circuit includes:
a first transistor, wherein a control electrode of the first transistor is connected with the first data node, a first electrode of the first transistor is connected with the supply voltage node, and a second electrode of the first transistor is connected with the second data node; and
a second transistor, wherein a control electrode of the second transistor is connected with the second data node, a first electrode of the second transistor is connected with the supply voltage node, and a second electrode of the second transistor is connected with the first data node.

18. The memory device of claim 16, wherein
the set control circuit includes a third transistor, wherein a control electrode of the third transistor is configured to receive the set signal, a first electrode of the third transistor is connected with the ground voltage node, and a second electrode of the third transistor is connected with the second data node; and
the reset setting control circuit includes a fourth transistor, wherein a control electrode of the fourth transistor is configured to receive the reset signal, a first electrode of the fourth transistor is connected with the ground voltage node, and a second electrode of the fourth transistor is connected with the first data node.

19. The memory device of claim 13, wherein the latch transmission circuit includes a fifth transistor and a sixth transistor connected in series, wherein the fifth transistor and the sixth transistor are P-type transistors.

20. A memory system, comprising:
one or more memory devices, wherein each of the memory devices includes:
a memory cell array connected with a plurality of bit lines; and
a plurality of page buffers, wherein each of the page buffers is connected with one of the bit lines, and is configured to perform a sense operation based on a current level of the bit line, and each of the page buffers includes:
a plurality of latch circuits, wherein each of the latch circuits includes:
a latch control configuration circuit connected with a first data node and a second data node, and configured to: configure the first data node and the second data node to different logic levels respectively in response to a configuration signal, wherein a logic level of the first data node is opposite to a logic level of the second data node; and
a latch transmission circuit connected with the first data node, the second data node, and a sense node, and configured to: couple the second data node with the sense node in response to a transmission signal, to transmit a configuration result of the latch control configuration circuit to the sense node; and
a memory controller connected with the memory devices and configured to control the memory devices.
